(19) United States
(12) Patent Application Publication
(10) Pub. No.: US 2015/0331062 A1
(43) Pub. Date: Nov. 19, 2015

(54) Failure Detection Method and Detection Device for Inverter

(71) Applicants: BOE TECHNOLOGY GROUP CO., LTD., Beijing (CN); BEIJING BOE ENERGY TECHNOLOGY CO., LTD., Beijing (CN)

(72) Inventors: Jia HE, Beijing (CN); Xiaoyan HAN, Beijing (CN); Ping ZHENG, Beijing (CN); Jin LI, Beijing (CN)

(21) Appl. No.: 14/597,311

(22) Filed: Jan. 15, 2015

(30) Foreign Application Priority Data
May 16, 2014 (CN) 201410208186.X

(51) Int. Cl. G01R 31/40; H02M 1/12

(52) U.S. Cl. CPC G01R 31/40; H02M 1/12

(57) ABSTRACT

The present disclosure provides a failure detection method for an inverter, which comprises steps of: performing Fourier transformation on output voltage signals of an inverter to obtain voltage harmonic signals; classifying the Fourier-transformed voltage harmonic signals; and determining a failure type corresponding to the Fourier-transformed voltage harmonic signals. Correspondingly, the present disclosure further provides a failure detection device for an inverter.

### CROSS-REFERENCE TO RELATED APPLICATION

This application claims the benefit of Chinese Patent Application No. 201410208186.X filed on May 16, 2014, with the State Intellectual Property Office of the P.R.C, the disclosure of which is incorporated herein by reference.

### BACKGROUND

The present disclosure relates to a field of failure detection of inverters, and particularly to a failure detection method for an inverter and a failure detection device for an inverter.

Inverters are transformers for converting a direct current into an alternating current, and are widely applied to electric apparatuses, such as electric tools, computers, TV sets, washing machines, fans, and the like. An output terminal of a cascaded inverter may output a plurality of electrical levels, and therefore the cascaded inverter is widely applied. With an increase in the number of the electrical levels output by a cascaded inverter, the number of power devices in a circuit also increases, so that both of the structure and control mode of the circuit are more complicated, and the failure rate is thus increased. Therefore, failure detection on an inverter is particularly important.

Existing detection methods for an inverter mainly include failure detection methods based on knowledge and experience and failure detection methods based on support vector machines. However, in these methods, detection needs to be performed on multiple locations in a circuit, so that the detection efficiency is low, the application range is narrow, and these methods cannot be applied to various circuits of different structures.

### SUMMARY

An objective of the present disclosure is to provide a failure detection method and a detection device for an inverter to improve the failure detection efficiency on an inverter.

One aspect of the present disclosure provides a failure detection method for an inverter, including steps of: performing Fourier transformation on output voltage signals of an inverter to obtain voltage harmonic signals; classifying the Fourier-transformed voltage harmonic signals; and determining a failure type corresponding to the Fourier-transformed voltage harmonic signals.

According to an embodiment of the present disclosure, the Fourier-transformed voltage harmonic signals may be classified by using a neural network model.

According to an embodiment of the present disclosure, the output voltage signals of the inverter may include analog voltage signals, and the step of performing Fourier transformation on output voltage signals of an inverter may include steps of: converting the analog voltage signals into digital voltage signals; and performing Fourier transformation on the converted digital voltage signals.

According to an embodiment of the present disclosure, the Fourier transformation may include fast Fourier transformation.

According to an embodiment of the present disclosure, the step of classifying the Fourier-transformed voltage harmonic signals may include steps of: performing normalization on input signals of the neural network model; and performing dimensionality reduction on the normalized signals.

According to an embodiment of the present disclosure, before the step of performing Fourier transformation on output voltage signals of an inverter, training of the neural network model may be performed at least once, and the training may include steps of: performing Fourier transformation on the output signals of the inverter in a preset failure state, so as to obtain voltage harmonic signals; inputting the Fourier-transformed voltage harmonic signals into the neural network model; and determining a weight of the neural network model according to the input signals of the neural network model and a preset output signal of the neural network model, so as to determine a classification mechanism of the neural network model, the preset output signal being corresponding to the preset failure state.

According to an embodiment of the present disclosure, training of the neural network model may be performed multiple times. A modulation ratio of the inverter may be adjusted, so as to obtain a plurality of different modulation ratios, and training of the neural network model may be performed once with respect to each of the obtained modulation ratios.

According to an embodiment of the present disclosure, before the step of performing Fourier transformation on output voltage signals of an inverter, testing of the neural network model may be performed at least once, and the testing may include steps of: adjusting the modulation ratio of the inverter to a value different from the modulation ratio in corresponding training, and performing Fourier transformation on the output signals of the inverter in the preset failure state, so as to obtain voltage harmonic signals; inputting the Fourier-transformed voltage harmonic signals into the neural network model; and comparing an actual output signal of the neural network model with the preset output signal to determine whether they are consistent.

According to an embodiment of the present disclosure, testing of the neural network model may be performed multiple times.

Another aspect of the present disclosure provides a failure detection device for an inverter, including: a signal transformation unit, which is configured to perform Fourier transformation on output voltage signals of an inverter to obtain voltage harmonic signals; a classification unit, which is configured to classify the Fourier-transformed voltage harmonic signals; and a failure determination unit, which is configured to determine a failure type corresponding to the Fourier-transformed voltage harmonic signals.

According to an embodiment of the present disclosure, a neural network model may be provided in the classification unit, and the Fourier-transformed voltage harmonic signals are classified by using the neural network model.

According to an embodiment of the present disclosure, the output voltage signals of the inverter may include analog voltage signals, and the failure detection device may further include an analog-to-digital conversion unit connected between the inverter and the signal transformation unit, wherein the analog-to-digital conversion unit is configured to convert the analog voltage signals into digital voltage signals, and the signal transformation unit may perform Fourier transformation on the converted digital voltage signals.

According to an embodiment of the present disclosure, the classification unit may perform normalization on input signals of the neural network model and then perform dimensionality reduction on the normalized signals.

According to the failure detection method and the failure detection device provided by the present disclosure, by performing Fourier transformation on output voltage signals of an inverter, time domain signals which are difficult to process are converted into frequency domain signals which are easy to analyze. As the Fourier transformation may be applied to various types of signals, compared with the detection on multiple locations in a circuit of an inverter in the prior art, detection efficiency is improved, and application range is widened. On the other hand, voltage harmonic signals are classified by using a neural network model to determine a failure type corresponding to the voltage harmonic signals, and thus a failure type corresponding to output voltage signals of the inverter is determined, so that the detection efficiency of the inverter is improved, and both of the usage of voltage detection devices and the detection cost may also be reduced.

### BRIEF DESCRIPTION OF DRAWINGS

The accompanying drawings, which constitute a part of the specification, are used for providing further understanding of the present disclosure, and explaining the present disclosure together with specific embodiments, but are not intended to limit the present disclosure. In the drawings:

FIG. 1 is a flowchart of a failure detection method for an inverter according to an embodiment of the present disclosure;

FIG. 2 is a flowchart of a failure detection method for an inverter according to another embodiment of the present disclosure;

FIG. 3 is a flowchart illustrating training steps shown in FIG. 2;

FIG. 4 is a flowchart illustrating testing steps shown in FIG. 2; and

FIG. 5 is a schematic diagram of a structure of a failure detection device for an inverter according to an embodiment of the present disclosure.

### DETAILED DESCRIPTION

Specific embodiments of the present disclosure will be described below in details with reference to the accompanying drawings. It should be understood that the specific embodiments described herein are merely used for describing and explaining the present disclosure, rather than limiting the present disclosure.

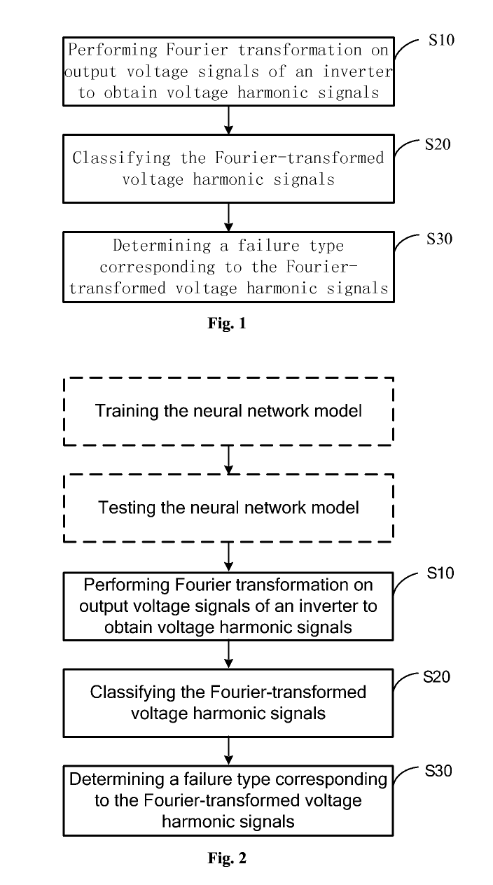

FIG. 1 is a flowchart of a failure detection method for an inverter according to an embodiment of the present disclosure. Referring to FIG. 1, the failure detection method includes steps of:

performing Fourier transformation on output voltage signals of an inverter to obtain voltage harmonic signals (S10);

classifying the Fourier-transformed voltage harmonic signals (S20); and

determining a failure type corresponding to the Fourier-transformed voltage harmonic signals (S30).

The Fourier-transformed voltage harmonic signals may be classified by using many methods. According to an embodiment of the present disclosure, the Fourier-transformed voltage harmonic signals may be classified by using a neural network model, so as to improve classification accuracy and classification rate.

Specifically, an input layer of the neural network model may be provided with 20 to 50 input nodes, and Fourier-transformed harmonic signals of all orders are input into the input nodes, respectively. For example, a fundamental harmonic signal is input into a first input node, a first harmonic signal is input into a second input node, a second harmonic signal is input into a third input node, and so on. The number of output nodes of an output layer of the neural network model may be set according to the number of types of possible failures of the inverter. By taking an inverter including 10 power devices as an example, when the case in which one of the power devices fails is taken into account only, there are 10 types of failure states of the inverter, i.e., the first power device failing, the second power device failing, the third power device failing, etc., respectively. In this case, the number of the output nodes of the neural network model may be set to be four, and each node may output two signals, i.e., 0 and 1, so that the neural network model may output 16 different signals in total to cover 10 different signals and 10 failure types. For example, when the output of the neural network model is 0001, it may be determined that the first power device of the inverter fails; when the output of the neural network model is 0010, it may be determined that the second power device of the inverter fails; when the output of the neural network model is 0011, it may be determined that the third power device of the inverter fails; and so on.

The neural network model may have various output forms. For example, the output layer may be provided with a plurality of nodes, or a plurality of neural network sub-models are provided, and the output layer of each neural network sub-model is provided with one output node, as long as different signals may be output to distinguish different failure states.

The use of neural network model may improve classification efficiency. For an inverter that has complicated structure and to which multiple types of failures may possibly occur, the use of neural network model may improve detection efficiency, and therefore, the present disclosure is particularly applicable to cascaded inverters.

Generally, the output voltage signals of the inverter include analog voltage signals, and accordingly, the step of S10 may include steps of:

S11: converting the output analog voltage signals of the inverter into digital voltage signals; and

S12: performing Fourier transformation on the converted digital voltage signals.

Those skilled in the art can understand that the step of S11 may be executed by performing sampling, maintaining, quantifying, coding and other processes on the output analog voltage signals of the inverter. In addition, before sampling, the analog voltage signals may be filtered to reduce aliasing components in the analog voltage signals.

To improve the efficiency of Fourier transformation, according to an embodiment of the present disclosure, the Fourier transformation may include fast Fourier transformation, so that the operation amount may be reduced and the operation time may be saved.

To improve the classification rate of the neural network model, the step of S20 may include steps of:

S21: performing normalization on input signals of the neural network model; and

S22: performing dimensionality reduction on the normalized signals.

The normalization method is not specifically limited in the present disclosure. For example, the normalization may be performed by using Z-scoring, that is, for an array X=[x₁,x₂, . . . xₙ] to be normalized, the mean value of the array is X_{M} and the standard deviation is X_{S}, and the normalized value for xᵢ(1≦i≦n) is (xᵢ−X_{M})/X_{S}.

In addition, the dimensionality reduction may be performed by using principal component analysis, so that the number of the input harmonic signals is reduced, so as to further improve the classification rate of the neural network model. For example, the dimensionality of an input signal of the input layer of the neural network model is reduced to 5-8 from 20-50, that is, 20-50 Fourier-transformed harmonic signals are converted into 5-8 harmonic signals, and the 5-8 converted harmonic signals contain principal information in the original 20-50 harmonic signals. Reduction in dimensionality of an input signal can improve classification efficiency of the neural network model, but has little influence on classification accuracy.

FIG. 2 is a flowchart of a failure detection method for an inverter according to another embodiment of the present disclosure.

To improve the classification effect of the neural network efficiency, according to an embodiment of the present disclosure, before the step of S10, training of the neural network model may be performed at least once, and testing of the neural network model may be performed at least once.

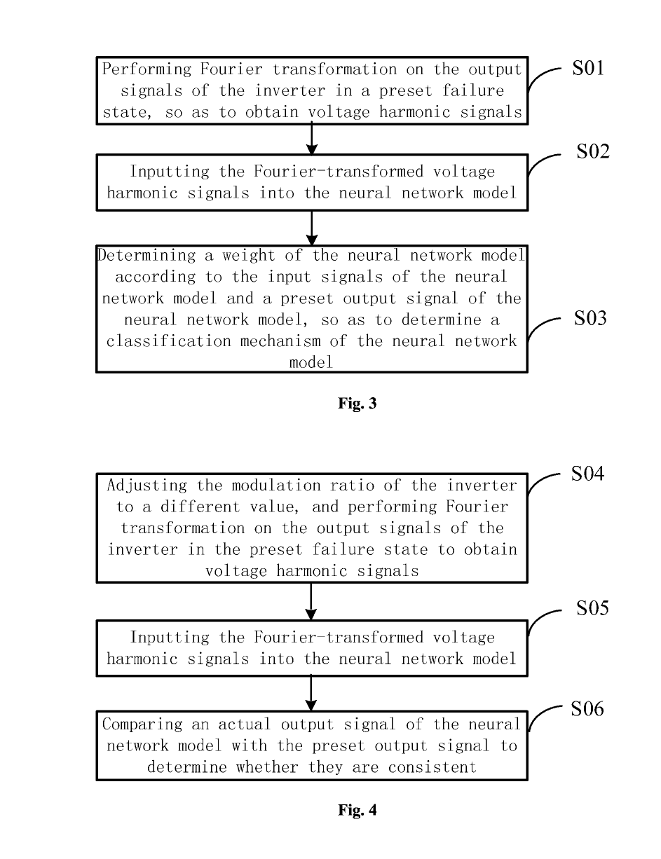

FIG. 3 is a flowchart illustrating training steps in FIG. 2. The training may include steps of:

S01: performing Fourier transformation on the output signals of the inverter in a preset failure state, so as to obtain voltage harmonic signals;

S02: inputting the Fourier-transformed voltage harmonic signals into the neural network model; and

S03: determining a weight of the neural network model according to the input signals of the neural network model and a preset output signal of the neural network model, so as to determine a classification mechanism of the neural network model, the preset output signal being corresponding to the preset failure state.

For example, the preset failure state may be set to be the first power device failing, the corresponding preset output signal is 0001, and the weight of the neural network model is initialized to be an initial value; Fourier transformation is performed on the output signals of the inverter, and the Fourier-transformed voltage harmonic signals are input into the input layer of the neural network model; and the weight of the neural network is adjusted according to a difference between an output signal of the neural network model and the preset output signal (0001), until a deviation between the output signal of the neural network model and the present output signal is within a preset range, or until the number of times of weight adjustments reaches a preset number. At this point, the obtained weight may be used as the weight of the neural network model, thus the classification mechanism of the neural network model is determined. That is, during detection of a failure state of the inverter, if the output signal of the neural network model is 0001, it is determined that the failure of the inverter is the first power device failing. It should be understood that the weight may include a weight between the input layer and a hidden layer of the neural network model and a weight between the hidden layer and the output layer of the neural network model.

Training of the neural network model may be performed only once, or be performed multiple times. To improve the accuracy of the weight obtained by training, according to an embodiment of the present disclosure, performing multiple times of training of the neural network model may include: adjusting a modulation ratio of the inverter to obtain a plurality of different modulation ratios, and performing training of the neural network model once with respect to each of the obtained modulation ratios. For example, the modulation ratio of the inverter may be adjusted to be 0.6, 0.7, 0.8 and 0.9, respectively; when the first power device of the inverter fails, the corresponding preset output signal is set to be 0001; when the second power device fails, the corresponding preset output signal is set to be 0010; when the third power device fails, the corresponding preset output signal is set to be 0011; and so on. With respect to each modulation ratio, Fourier transformation is performed on the output signals of the inverter corresponding to all failure states, and a signal matrix formed by the voltage harmonic signals corresponding to the plurality of output signals is used as an input of the neural network model, and a signal matrix formed by the preset output signals corresponding to the plurality of output signals is used as an output of the neural network model, so as to determine the weight of the neural network model. It should be understood that, when the modulations ratios are different, the weight of the neural network model obtained by training is the same.

FIG. 4 is a flowchart illustrating testing steps in FIG. 2. The testing may include steps of:

S04: adjusting the modulation ratio of the inverter to a value different from the modulation ratio in corresponding training, and performing Fourier transformation on the output signals of the inverter in the preset failure state, so as to obtain voltage harmonic signals;

S05: inputting the Fourier-transformed voltage harmonic signals into the neural network model; and

S06: comparing an actual output signal of the neural network mode with the preset output signal, so as to determine whether they are consistent.

As described in the above example, training of the neural network model is performed in the case that the modulation ratios of the inverter are 0.6, 0.7, 0.8 and 0.9, respectively, in testing, the modulation ratio of the inverter may be adjusted to any value different from the modulation ratio in the training For example, the modulation ratio in the testing may be 0.65, during training, the preset output signal corresponding to the first power device failing is 0001, the output voltage signals of the tested inverter in the first power device failing are Fourier transformed, then are input into the neural network model, and if the actual output signal of the neural network model is 0001, the training of the neural network model is successful. It should be understood that, the weight of the neural network is determined by training according to various failure types and the plurality of preset output signals corresponding to the respective failure types, correspondingly, in testing, it is required to compare actual output signals corresponding to the respective failure types with the plurality of preset output signals corresponding to the respective failure types, and the training of the neural network model is successful when the actual output signals corresponding to the respective failure types and the plurality of preset output signals corresponding to the respective failure types are all identical. That is, when the preset output signal corresponding to the second power device failing is 0010, the actual output signal of the neural network model in testing should be also 0010; when the preset output signal corresponding to the third power device failing is 0011, the actual output signal of the neural network model in testing should be also 0011; and so on. Otherwise, it may be considered that the training of the neural network model fails.

To improve the testing effects of the neural network model, according to an embodiment of the present disclosure, testing of the neural network model may be performed multiple times. The modulation ratio in each testing is different from that in training.

The foregoing description shows the failure detection method for an inverter provided by the present disclosure. It can be seen that, by performing Fourier transformation on output voltage signals of an inverter, time domain signals which are difficult to process are converted into frequency domain signals which are easy to analyze. As the Fourier transformation may be applied to various types of signals, compared with the detection on multiple locations in a circuit of an inverter in the prior art, the detection efficiency is improved, and the application range is widened. On the other hand, voltage harmonic signals are classified by using a neural network model to determine a failure type corresponding to the voltage harmonic signals, and thus a failure type corresponding to output voltage signals of the inverter is determined, so that detection efficiency of the inverter is improved. As the detection on multiple locations in a circuit of an inverter is avoided, both the usage of voltage detection devices and the detection cost are reduced.

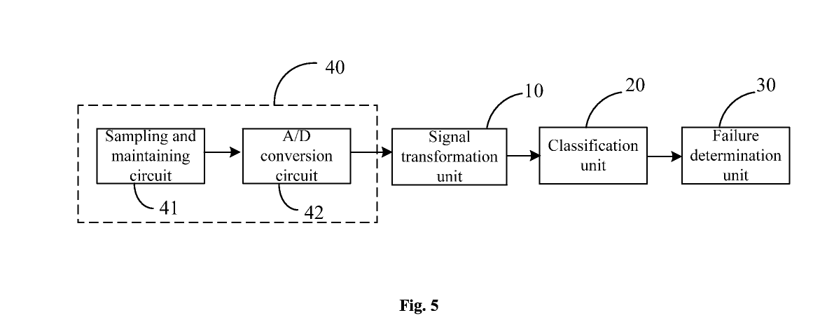

FIG. 5 is a schematic diagram of a structure of a failure detection device for an inverter according to an embodiment of the present disclosure.

As shown in FIG. 5, the failure detection device may include a signal transformation unit 10, a classification unit 20 and a failure determination unit 30. The signal transformation unit 10 is configured to perform Fourier transformation on output voltage signals of an inverter to obtain voltage harmonic signals. The classification unit 20 is configured to classify the Fourier-transformed voltage harmonic signals. The failure determination unit 30 is configured to determine a failure type corresponding to the Fourier-transformed voltage harmonic signals.

The classification unit 20 may classify the Fourier-transformed voltage harmonic signals in many ways. According to an embodiment of the present disclosure, a neural network model may be provided in the classification unit 20, and the Fourier-transformed voltage harmonic signals are classified by using the neural network model.

Generally, the output voltage signals of the inverter include analog voltage signals. To facilitate processing output voltage signals of the inverter, the failure detection device provided by the embodiment of the present disclosure further includes an analog-to-digital conversion unit 40 connected between the inverter and the signal transformation unit 10. The analog-to-digital conversion unit 40 may convert the analog voltage signals output by the inverter into digital voltage signals, and the signal transformation unit 10 may perform Fourier transformation on the converted digital voltage signals.

The analog-to-digital conversion unit 40 may include a sampling and maintaining circuit 41 and an A/D conversion circuit 42. To reduce aliasing components in the analog voltage signals, the analog-to-digital conversion unit 40 may further include an anti-aliasing filter (not shown).

To improve the detection efficiency, according to an embodiment of the present disclosure, the classification unit 20 may perform normalization on input signals of the neural network model and then perform dimensionality reduction on the normalized signals, so as to improve the classification efficiency of the neural network model.

It should be understood that, the above embodiments are merely exemplary embodiments used for describing the principle of the present disclosure, but the present disclosure is not limited thereto. For a person skilled in the art, various variations and improvements without may be made without departing from the spirit and essence of the present disclosure, and these variations and improvements shall fall into the protection scope of the present disclosure.

1. A failure detection method for an inverter, comprising steps of:
performing Fourier transformation on output voltage signals of an inverter to obtain voltage harmonic signals;
classifying the Fourier-transformed voltage harmonic signals; and
determining a failure type corresponding to the Fourier-transformed voltage harmonic signals.

2. The failure detection method for an inverter according to claim 1, wherein the Fourier-transformed voltage harmonic signals are classified by using a neural network model.

3. The failure detection method for an inverter according to claim 1, wherein the output voltage signals of the inverter comprise analog voltage signals, and the step of performing Fourier transformation on output voltage signals of an inverter comprises steps of:
converting the analog voltage signals into digital voltage signals; and
performing Fourier transformation on the converted digital voltage signals.

4. The failure detection method for an inverter according to claim 3, wherein the Fourier transformation comprises fast Fourier transformation.

5. The failure detection method for an inverter according to claim 2, wherein the step of classifying the Fourier-transformed voltage harmonic signals comprises steps of:
performing normalization on input signals of the neural network model; and
performing dimensionality reduction on the normalized signals.

6. The failure detection method for an inverter according to claim 2, wherein, before the step of performing Fourier transformation on output voltage signals of an inverter, training of the neural network model is performed at least once, and the training comprises steps of:
performing Fourier transformation on the output signals of the inverter in a preset failure state, so as to obtain voltage harmonic signals;
inputting the Fourier-transformed voltage harmonic signals into the neural network model; and
determining a weight of the neural network model according to the input signals of the neural network model and a preset output signal of the neural network model, so as to determine a classification mechanism of the neural network model, the preset output signal being corresponding to the preset failure state.

7. The failure detection method for an inverter according to claim 6, wherein training of the neural network model is performed multiple times,
wherein, a modulation ratio of the inverter is adjusted, so as to obtain a plurality of different modulation ratios, and training of the neural network model is performed once with respect to each of the obtained modulation ratios.

8. The failure detection method for an inverter according to claim 6, wherein, before the step of performing Fourier transformation on output voltage signals of an inverter, testing of the neural network model is performed at least once, and the testing comprises steps of:
adjusting the modulation ratio of the inverter into a value different from the modulation ratio in corresponding training, and performing Fourier transformation on the output signals of the inverter in the preset failure state to obtain voltage harmonic signals;
inputting the Fourier-transformed voltage harmonic signals into the neural network model; and
comparing an actual output signal of the neural network model with the preset output signal to determine whether they are consistent.

9. The failure detection method for an inverter according to claim 8, wherein testing of the neural network model is performed multiple times.

10. A failure detection device for an inverter, comprising:
a signal transformation unit, configured to perform Fourier transformation on output voltage signals of an inverter to obtain voltage harmonic signals;
a classification unit, configured to classify the Fourier-transformed voltage harmonic signals; and
a failure determination unit, configured to determine a failure type corresponding to the Fourier-transformed voltage harmonic signals.

11. The failure detection device for an inverter according to claim 10, wherein a neural network model is provided in the classification unit, and the Fourier-transformed voltage harmonic signals are classified by using the neural network model.

12. The failure detection device for an inverter according to claim 10, wherein the output voltage signals of the inverter comprise analog voltage signals, and the failure detection device further comprises an analog-to-digital conversion unit connected between the inverter and the signal transformation unit, the analog-to-digital conversion unit is configured to convert the analog voltage signals into digital voltage signals, and the signal transformation unit performs Fourier transformation on the converted digital voltage signals.

13. The failure detection device for an inverter according to claim 11, wherein the classification unit performs normalization on input signals of the neural network model, and then performs dimensionality reduction on the normalized signals.
